(19) United States
(12) Patent Application Publication
(10) Pub. No.: US 2008/0265923 A1
(43) Pub. Date: Oct. 30, 2008

(54) Leadframe Configuration to Enable Strip Testing of SOT-23 Packages and the Like

(75) Inventors: Rangsun Kitnarong, Muang Nonthaburi (TH); Kanit Jarupate, Muang Chacherngsao (TH)

Correspondence Address: BAKER BOTTS, LLP, 910 LOUISIANA, HOUSTON, TX, 77002-4995, US

(73) Assignee: Microchip Technology Incorporated

(21) Appl. No.: 12/026,653

(22) Filed: Feb. 6, 2008

Related U.S. Application Data
(60) Provisional application No. 60/914,518, filed on Apr. 27, 2007.

(51) Int. Cl. G01R 31/26

(52) U.S. Cl. 324/755

(57) ABSTRACT

A reduced width tie bar and a common lead hold a die paddle of each integrated circuit SOT-23 package to a leadframe within a strip of leadframes after isolating signal leads from the leadframe. Strip testing of most devices in the SOT-23 lead packages may then be performed. The common lead may be at the center of an edge of the SOT-23 package. Also the common lead may be any one of the leads of the SOT-23 package. The reduced width tie bar may be downstream of the epoxy encapsulation flow for better package integrity.

### RELATED PATENT APPLICATION

This application claims priority to commonly owned U.S. Provisional Patent Application Ser. No. 60/914,518; filed Apr. 27, 2007; entitled “Leadframe Configuration Strip Testing of SOT-23 Packages,” by Randall L. Drwinga, David L. Wilkie, Rangsun Kitnarong and Kanit Jarupate; and this application is related to commonly owned U.S. patent application Ser. No. ______, filed ______, 2007; entitled “Strip Testing of SOT-23 Packages and The Like,” by Randall L. Drwing a and David L. Wilkie; wherein both are hereby incorporated by reference herein for all purposes.

### TECHNICAL FIELD

The present disclosure relates to SOT-23 three lead, five lead and six lead integrated circuit packages and the like, that retain connection to a leadframe of one common lead and a reduced width tie bar attached to each die paddle of respective leadframes, e.g., strip of leadframes, after isolation of the signal leads from the leadframes, and more particularly to, the one common lead and the reduced width tie bar of each of the respective leadframes providing a stable platform and adequate support for enabling highly parallel leadframe strip testing of the integrated circuit packages before removal from the strip of leadframes.

### BACKGROUND

Strip testing of integrated circuit packages greatly increases the ability to simultaneously test in parallel many integrated circuits in their packages by testing them while still in their assembly strip of leadframes. Integrated circuit dice are attached to paddles in the strip of leadframes before being encapsulated, e.g., molded over, with molding compound to form a package (enclosure) around each integrated circuit die. The strip of leadframes has a uniform layout for a particular package, so the location of an external “lead” or “pin” is always consistent. To strip test, a step is added called “isolation” which makes each functional pin electrically isolated from its respective leadframe, i.e., separating each integrated circuit from every other one on the strip of leadframes. Prior to this, all of the pins are electrically connected to each other through the common strip attached to the leadframes, and so each integrated circuit could not be stimulated or measured individually. This ability to have each pin electrically isolated is key to full functional testing of each individual integrated circuit package before removal of each of the integrated circuit packages from the strip of leadframes. Standard parallel testing can then be done by testing each isolated integrated circuit separately and independently from the other integrated circuits in the strip.

This is only possible if the external connections, e.g., “pins” or “leads,” of the integrated circuit packages can be electrically isolated for testing. By isolating the pins, but leaving the units connected in the strip of leadframes by tie bars, testing could be achieved. Tie bars are metal pieces that extend from the paddle to the leadframe to provide mechanical strength, but are not functional pins. They are trimmed off of the package in the “trim/form” operation, which occurs after assembly in traditional flow, or after test in a strip test flow. Present technology strip testing accomplishes this by leaving at least two “tie bars” connected to the leadframe used during the package encapsulation process.

However, some packages do not have tie bars. One such package is the SOT-23 family of integrated circuit packages that may have three, five and six lead configurations. The SOT-23 package is small, and the use of traditional tie bars in this package leads to fabrication problems, such as uneven molding compound flow, package stress, and package cracking during the “trim/from” fabrication process. If all the functional pins of an SOT-23 package are isolated, the SOT-23 parts will fall out of the strip, because there is nothing to hold them in place. The lack of tie bars has made the SOT-23 package and packages like it impossible to strip test, and adding two tie bars results in increased package stress and unreliability during the molding compound flow process and/or trim/form that have not been solved to date.

### SUMMARY

Therefore a need exists to reduce cost, improve capacity, and improve quality by providing two support points after isolation of the active leads from the leadframe so as to allow strip testing of integrated circuit packages like the SOT-23 (Small Outline Transistor) family of packages without compromising package fabrication and reliability.

According to teachings of this disclosure, by adding one reduced width tie bar in addition to a common, e.g., ground or Vss, lead (pin) to a die paddle of each integrated circuit SOT-23 package and the like, the SOT-23 packages are securely held to their respective leadframes by the one reduced width tie bar and the common lead, and thereby allows for strip testing of most devices in the SOT-23 packages that have the common lead (pin) at the center of an edge of the SOT-23 package. The reduced width tie bar may be downstream of the epoxy encapsulation flow for better package integrity.

According to a specific example embodiment of this disclosure, a strip of leadframes configured for strip testing of integrated circuit devices comprises: a plurality of leadframes within a strip, each of the plurality of leadframes comprising an integrated circuit device; each of the integrated circuit devices comprising a die paddle, an integrated circuit die attached to a face of the die paddle, a common lead connected to an edge of the die paddle and to a respective one of the plurality of leadframes, a reduced width tie bar connected to another edge of the die paddle and to the respective one of the plurality of leadframes, at least two signal leads electrically coupled to the integrated circuit die, and the common lead electrically coupled to the integrated circuit die; wherein the at least two signal leads are electrically isolated from the respective ones of the plurality of leadframes so that each of the plurality of integrated circuit devices can be electrically tested before being removed from the plurality of leadframes within the strip.

### BRIEF DESCRIPTION OF THE DRAWINGS

A more complete understanding of the present disclosure may be acquired by referring to the following description taken in conjunction with the accompanying drawings wherein:

FIG. 1 is a schematic plan view of a prior technology strip of leadframes comprising a plurality of SOT-23 package integrated circuit devices before and after isolation of the signal leads of each of the integrated circuit devices from their respective leadframes;

FIG. 2 is a schematic plan view of a strip of leadframes comprising a plurality of SOT-23 package integrated circuit devices before and after isolation of the signal leads of each of the integrated circuit devices from the leadframe, according to a specific example embodiment of this disclosure; and

FIG. 3 are schematic plan views of SOT-23 integrated circuit packages.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawing, the details of specific example embodiments are schematically illustrated. Like elements in the drawings will be represented by like numbers, and similar elements will be represented by like numbers with a different lower case letter suffix.

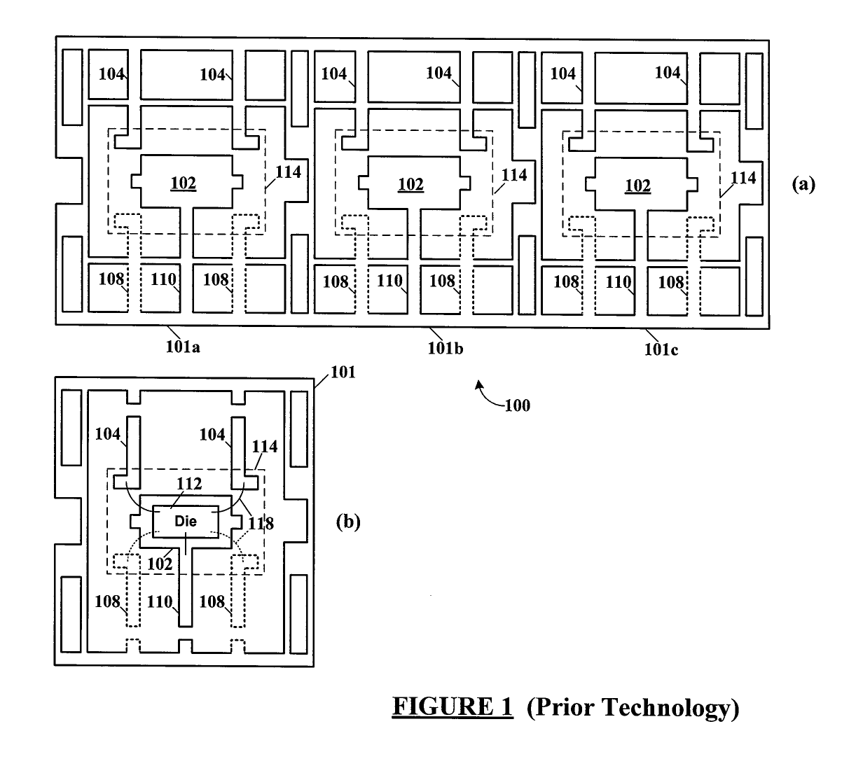

Referring to FIG. 1, depicted is a schematic plan view of a prior technology strip of leadframes comprising a plurality SOT-23 package integrated circuit devices before and after isolation of the signal leads, e.g., pins, of each of the integrated circuit devices from the leadframe. A strip of leadframes 100 comprises a stamped or etched pattern of leadframes 101. Each of the leadframes 101 comprises signal and/or power supply leads 104 (three, five and six lead SOT23 devices), signal leads 108 (five and six lead SOT23 devices), signal lead 106 (six-lead SOT23 devices), common, e.g., ground or Vss, lead 110, and integrated circuit die paddle 102. During fabrication of the SOT23 integrated circuit packages 114, an integrated circuit die 112 is attached to each of the die paddles 102.

Then bond wires 118 are used to electrically connect bond pads on each of the integrated circuit dice 112 to the ground lead 110, the signal and/or power supply leads 104 (three, five and six lead SOT23 packages), the signal leads 108 (five and six lead SOT23 packages) and the signal leads 106 (six lead SOT23 packages). After the bond wires 118 have been installed, package encapsulation flows over each die 112, die paddle 102, and proximal ends of the common lead 110, the signal and/or power supply leads 104, the signal leads 108 (five lead SOT23 packages), the signal leads 106 (six lead SOT23 packages). Integrated circuit packages 114 are thereby formed.

Next the distal ends of the common lead 110, the signal and/or power supply leads 104 the signal leads 108 (five-lead SOT23 packages) and the signal leads 106 (six lead SOT23 packages) are separated (electrically isolated) from the leadframe 101, i.e., FIG. 1(b). This is required for individual electrical testing of each of the SOT23 integrated circuit packages 114. Once all of the leads 104, 106, 108 and 110 are separated from the leadframes 101, the SOT23 integrated circuit packages 114 no longer are supported by the leadframes 101 and must be individually tested, which is both a time consuming and expensive process.

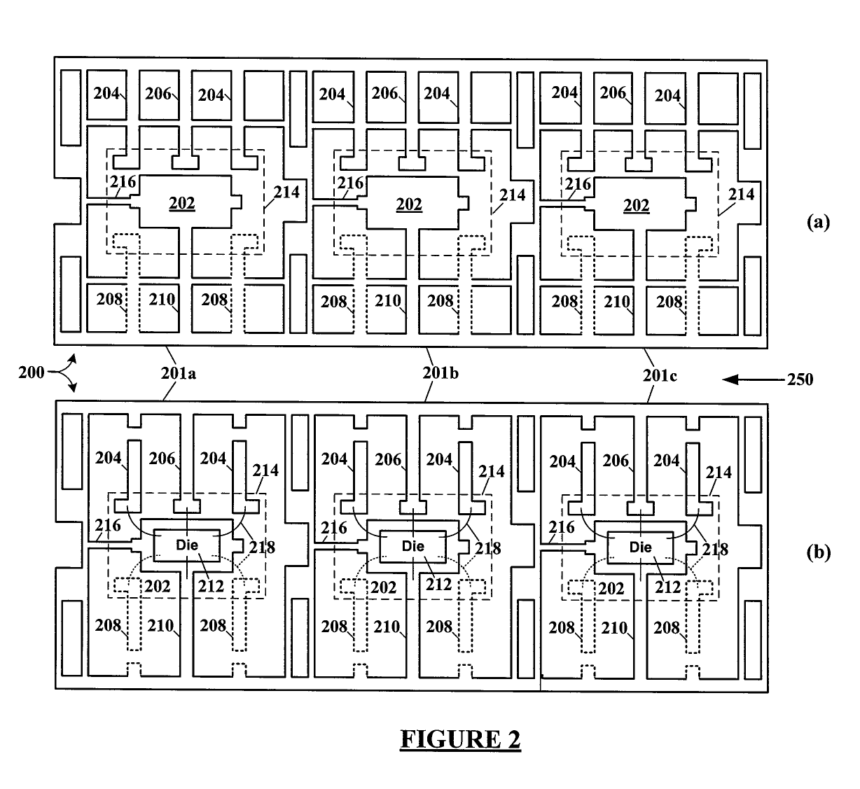

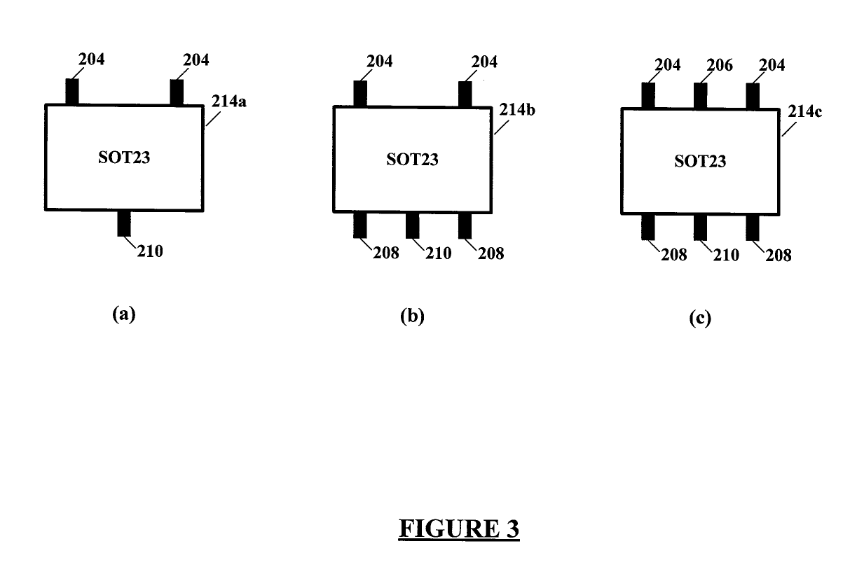

Referring to FIG. 2, depicted is a schematic plan view of a strip of leadframes comprising a plurality of SOT-23 package integrated circuit devices before and after isolation of the signal leads of each of the integrated circuit devices from the leadframe, according to a specific example embodiment of this disclosure. A strip of leadframes 200 comprises a stamped or etched pattern of leadframes 201. Each of the leadframes 201 comprises signal and/or power supply leads 204 (three, five and six lead SOT23 devices), signal leads 208 (five and six lead SOT23 devices), signal lead 206 (six lead SOT23 devices), a common, e.g., ground or Vss, lead 210, a reduced width tie bar 216, and an integrated circuit die paddle 202. During fabrication of each SOT23 integrated circuit package 214 (see FIG. 3), an integrated circuit die 212 is attached to each of the die paddles 202.

Then bond wires 218 are used to electrically connect bond pads on each of the integrated circuit dice 212 to the signal and/or power supply leads 204, the signal leads 208 (five lead SOT23 packages), the signal leads 206 (six lead SOT23 packages), and the common leads 210. The signal leads 206 and 208 are not required for three lead SOT23 packages, and signal leads 206 are not required for five lead SOT23 packages. After the bond wires 218 have been installed, package encapsulation flows over each die 212, die paddle 202, and proximal ends of the common leads 210, the reduced width tie bar 216, the signal and/or power supply leads 204, and the signal leads 206 and 208 (when used). Integrated circuit packages 214 are thereby formed.

Next the distal ends of the signal and/or power supply leads 204, the signal leads 208 (five lead SOT23 packages) and the signal leads 206 (six lead SOT23 packages) are separated (electrically isolated) from the leadframe 201, e.g., FIG. 2(b). This is required for individual electrical testing of each of the SOT23 integrated circuit packages 214. However, a common lead 210 and a reduced width tie bar 216 remain attached to each of the leadframes 201. By leaving the common leads 210 and the reduced width tie bars 216 attached to each of the leadframes 201 within the strip of leadframes 200, automated highly parallel testing of the integrated circuit devices may be performed while still being supported by the strip of leadframes 200. The common leads 210 and the reduced width tie bars 216 adequately support the die paddles 202 (i.e., two support points) having the dies 212 thereon.

Thus, each integrated circuit device may be tested before and/or after encapsulation of the integrated circuit packages 214. After testing of each integrated circuit device, the distal ends of the common leads 210 are separated from the leadframe 201 within the strip of leadframes 200, and the reduced width tie bars 216 are separated at the package 214 encapsulation to produce a finished integrated circuit devices in SOT23 packages of either three, five or six lead configurations (see FIG. 3).

Referring to FIG. 3, depicted are schematic plan views of three, five and six lead SOT-23 integrated circuit packages. A three lead SOT23 integrated circuit package 214a is illustrated at FIG. 3(a), a five lead SOT23 integrated circuit package 214b is illustrated at FIG. 3(b), and a six lead SOT23 integrated circuit package 214c is illustrated at FIG. 3(c).

It is contemplated and within the scope of this disclosure that additional unused leads may remain attached to the die paddles 202 and leadframes 201 for holding the integrated circuit packages 214 (three lead and five lead SOT23 packages) to the strip of leadframes 200. It is also contemplated and within the scope of this disclosure that at least one of the signal leads may be used to electrically couple a power supply voltage to the integrated circuit device. However, for integrated circuit devices that generate their own operating voltage(s), e.g., wireless radio frequency identification devices (RFID) and/or passive devices like diode arrays and the like, all of the signal leads may be used for non-power source purposes.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. A strip of leadframes configured for strip testing of integrated circuit devices, comprising:
a plurality of leadframes within a strip, each of the plurality of leadframes comprising an integrated circuit device;
each of the integrated circuit devices comprising
a die paddle,
an integrated circuit die attached to a face of the die paddle,
a common lead connected to an edge of the die paddle and to a respective one of the plurality of leadframes,
a reduced width tie bar connected to another edge of the die paddle and to the respective one of the plurality of leadframes,
at least two signal leads electrically coupled to the integrated circuit die, and
the common lead electrically coupled to the integrated circuit die;
wherein the at least two signal leads are electrically isolated from the respective ones of the plurality of leadframes so that each of the plurality of integrated circuit devices can be electrically tested before being removed from the plurality of leadframes within the strip.

2. The strip of leadframes according to claim 1, wherein bond wires couple each integrated circuit die to respective ones of the at least two signal leads and the common lead.

3. The strip of leadframes according to claim 1, further comprising encapsulation of each of the die paddles, the integrated circuit dice, portions of the common leads, portions of the reduced width tie bars, and portions of the at least two signal leads so as to form packages for the plurality of integrated circuit devices.

4. The strip of leadframes according to claim 3, wherein the reduced width tie bars of each of the plurality of integrated circuit devices are downstream of encapsulation flow.

5. The strip of leadframes according to claim 3, wherein the packages are a three lead SOT23 packages.

6. The strip of leadframes according to claim 3, wherein the packages are five lead SOT23 packages.

7. The strip of leadframes according to claim 3, wherein the packages are six lead SOT23 packages.

8. The strip of leadframes according to claim 3, wherein distal ends of the at least two signal leads are separated from the leadframe before testing of the plurality of integrated circuit devices.

9. The strip of leadframes according to claim 3, wherein distal ends of the common leads are separated from the leadframe and the reduced width tie bars are separated from the packages after testing of the plurality of integrated circuit devices.

10. The strip of leadframes according to claim 1, wherein the plurality of leadframes within the strip are formed by stamping.

11. The strip of leadframes according to claim 1, wherein the plurality of leadframes within the strip are formed by etching.

12. The strip of leadframes according to claim 1, wherein the plurality of integrated circuit devices are tested in parallel.

13. The strip of leadframes according to claim 1, wherein the common leads are ground leads.

14. The strip of leadframes according to claim 1, wherein the common leads connect to a power source common.

15. The strip of leadframes according to claim 1, wherein a one of the at least two signal leads is a power lead that connects to a power source voltage.
